(19) United States
(12) Patent Application Publication
(10) Pub. No.: US 2015/0279870 A1
(43) Pub. Date: Oct. 1, 2015

(54) ARRAY SUBSTRATE, METHOD FOR MANUFACTURING THE SAME, AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventor: Xiaohui Jiang, Beijing (CN)

(21) Appl. No.: 14/437,016

(22) PCT Filed: Jul. 22, 2014
(86) PCT No.: PCT/CN2014/082733

§ 371 Date: Apr. 20, 2015

(30) Foreign Application Priority Data
Sep. 10, 2013 (CN) 201310409085.4

(51) Int. Cl. H01L 27/12; H01L 29/51; H01L 29/423; H01L 29/24; H01L 21/4757; H01L 21/477; H01L 21/768; H01L 21/441; H01L 29/49; H01L 29/786; H01L 29/66

(52) U.S. Cl. CPC H01L 27/1248; H01L 29/7869; H01L 29/512; H01L 29/518; H01L 29/42384; H01L 29/24; H01L 29/66969; H01L 27/127; H01L 21/477; H01L 21/76897; H01L 21/441; H01L 27/1288; H01L 29/517; H01L 29/4908; H01L 21/47573

(57) ABSTRACT

The present invention provides an array substrate, a method for manufacturing the same, and a display device, and relates to the field of a technology for manufacturing a display device. The present invention can solve the problem of high power consumption of an existing array substrate. The array substrate according to the present invention includes a gate, an active layer, and a gate insulating layer separating the gate and the active layer from each other. The gate insulating layer includes a two-layer structure consisted of an organic resin material layer and a protection layer. The organic resin material layer is in contact with the gate; and the protection layer is in contact with the active layer.

### FIELD OF THE INVENTION

The present invention relates to the field of a technology for manufacturing a display device, and in particular, relates to an array substrate, a method for manufacturing the same, and a display device.

### BACKGROUND OF THE INVENTION

Along with the continuous development of a liquid crystal display, a frequency of the driving circuit thereof is also increased continuously. The existing amorphous silicon is difficult to meet production and design requirements due to its low mobility, and low-temperature polysilicon (LTPS) has a high degree of process difficulty and poor film uniformity. Thus, an oxide thin film transistor (TFT) has been developed as required. The oxide thin film transistor is mainly used for increasing the mobility of carriers, and can be used for transparent display due to its good uniformity and simple process.

An oxide TFT array substrate is widely used in a display (e.g., a liquid crystal display), and specifically includes: a TFT substrate, a gate, which is arranged on the TFT substrate, of a thin film transistor, a gate insulating layer covering the gate, an active layer arranged on the gate insulating layer, a blocking layer covering the active layer, a source and a drain which are arranged on the blocking layer and are connected to the active layer through contact vias, a passivation layer covering the source and the drain, and a pixel electrode connected to the drain through a contact via which penetrates through the passivation layer.

Wherein, the gate insulating layer generally has a structure of composite layers formed of silicon dioxide and silicon nitride. The dielectric constant of each of the silicon dioxide and the silicon nitride ranges from 6.5 to 7.3, which causes the dielectric constant of the gate insulating layer to have a large value, thus the power consumption of the TFT array substrate during operation is high.

### SUMMARY OF THE INVENTION

In view of the above problem present in an existing array substrate, the technical problem to be solved by the present invention includes providing an array substrate having low power consumption, a method for manufacturing the same, and a display device.

A technical solution employed to solve the technical problem of the present invention is an array substrate including a gate, an active layer, and a gate insulating layer separating the gate and the active layer from each other, wherein, the gate insulating layer includes a two-layer structure consisted of an organic resin material layer and a protection layer; the organic resin material layer is in contact with the gate; and the protection layer is in contact with the active layer.

The gate insulating layer in the array substrate provided by the present invention has the two-layer structure including the organic resin material layer, which has a low dielectric constant. Thus, the array substrate has low power consumption.

Preferably, the organic resin material layer covers the gate, the protection layer is arranged on the organic resin material layer, and the active layer is arranged on the protection layer.

More preferably, the array substrate further includes a pixel electrode, a source, and a drain; and

the pixel electrode, the source, and the drain are formed by a single patterning process.

Preferably, the protection layer covers the active layer, the organic resin material layer is arranged on the protection layer, and the gate is arranged on the organic resin material layer.

Preferably, a material of the protection layer is any one of silicon dioxide, silicon nitride, and aluminum oxide, and a thickness of the protection layer ranges from 500 Å to 800 Å.

Preferably, a material of the organic resin material layer is a methacrylic phenolic resin or an epoxy acrylate resin, and a thickness of the organic resin material layer ranges from 1.5 μm to 2.0 μm.

Preferably, a material of the active layer is any one of indium gallium zinc oxide, indium zinc oxide, indium tin oxide, and indium gallium tin oxide, and a thickness of the active layer ranges from 1500 Å to 2200 Å.

A technical solution employed to solve the technical problem of the present invention is a display device including the array substrate as described above.

The display device according to the present invention has low power consumption because it includes the array substrate as described above.

A technical solution employed to solve the technical problem of the present invention is a method for manufacturing an array substrate, including steps of:

S11: forming a pattern including a gate on a substrate by a patterning process;

S12: forming an organic resin material layer on the substrate on which the step S11 has been completed, and forming a protection layer on the organic resin material layer; and

S13: forming a pattern including an active layer on the substrate subjected to the step S12 by a patterning process.

Preferably, the step S12 of forming the organic resin material layer includes steps of:
coating the organic resin material layer on the substrate on which the gate is formed by a spin coating method; and
performing annealing and curing on the organic resin material layer to form a flat surface.

Preferably, after the step S13, the method further includes steps of:

S14: forming a blocking layer on the substrate on which the active layer is formed, and forming contact vias which penetrate through the blocking layer in the blocking layer, wherein, the contact vias are used for connecting the active layer to the source and the drain;

S15: depositing a pixel electrode layer, a source-drain metal layer, and a photoresist layer successively on the substrate on which the step S14 has been completed, and exposing and developing the photoresist layer, so that there is no photoresist covering a conductive region of the active layer, while the photoresist on the regions corresponding to the source, the drain, and the pixel electrode is retained, and a thickness of the photoresist on the regions corresponding to the source and the drain is greater than a thickness of the photoresist on the region corresponding to the pixel electrode;

removing the photoresist which has the thickness of the photoresist on the region corresponding to the pixel electrode and an exposed portion of the source-drain metal layer by etching; and removing the photoresist of the remaining thickness, an exposed portion of the source-drain metal layer, and the exposed pixel electrode layer by etching.

More preferably, the step of exposing the photoresist layer is performed by using a grayscale mask.

A technical solution employed to solve the technical problem of the present invention is another method for manufacturing an array substrate, including steps of:

S21: forming a pattern including an active layer on a substrate by a patterning process;

S22: forming a protection layer on the substrate on which the step S21 has been completed, and forming an organic resin material layer on the protection layer; and

S23: forming a pattern including a gate on the substrate on which the step S22 has been completed by a patterning process.

### BRIEF DESCRIPTION OF THE DRAWINGS

FIG. 1 is a diagram showing a structure of an array substrate according to a first embodiment of the present invention; and

FIGS. 2A to 2F are a flowchart showing a method for manufacturing an array substrate according to a third embodiment of the present invention.

Reference numerals: 1—substrate; 2—gate; 3—organic resin material layer; 4—protection layer; 5—active layer; 6—blocking layer; 7—pixel electrode; 8—source and drain; and 9—photoresist layer.

### DETAILED DESCRIPTION OF THE EMBODIMENTS

For better understanding the technical solutions of the present invention by a person skilled in the art, the present invention will be further described in detail with reference to the drawings and specific embodiments.

A first embodiment of the present invention will be described below.

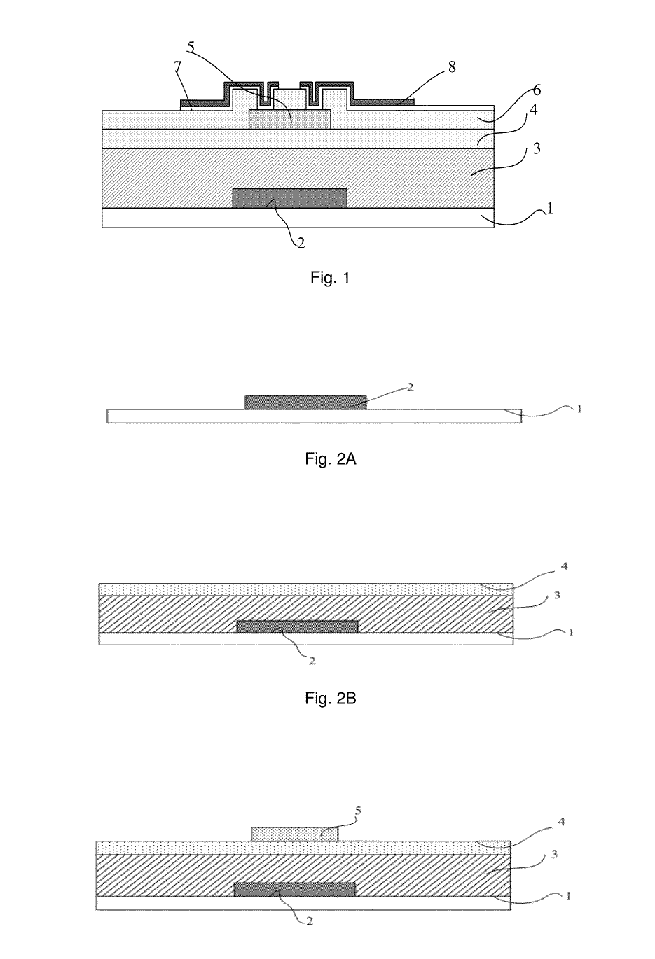

As shown in FIG. 1, the present embodiment provides an array substrate including a gate 2, an active layer 5, and a gate insulating layer separating the gate 2 and the active layer 5 from each other, wherein, the gate insulating layer includes a two-layer structure consisted of an organic resin material layer 3 and a protection layer 4. Further, the organic resin material layer 3 is in contact with the gate 2; and the protection layer 4 is in contact with the active layer 5.

One layer in the two-layer structure of the gate insulating layer of the array substrate according to the present embodiment is the organic resin material layer 3, and a material of the organic resin material layer 3 has a low dielectric constant generally ranging from 3.0 to 3.7. Thus, the array substrate has low power consumption. As compared with an existing gate insulating layer, the organic resin material layer 3 can be formed to be thicker in the present embodiment, that is, a distance between the gate 2 and the active layer 5 in a thin film transistor can be increased, causing a capacitance value of a storage capacitor (which is formed of a gate metal line and a source-drain metal line which are opposite to each other) in the array substrate to be decreased. In turn, the power consumption of the array substrate can be lowered. Further, the protection layer 4 is formed on the organic resin material layer 3, and thus can effectively prevent the hydroxyls in the organic resin material layer 3 from combining with oxygen ions in a material (e.g., a metal oxide semiconductor material) of the active layer 5; this combination will decrease the performance of the active layer 5.

As an implementation of the present embodiment, preferably, the organic resin material layer 3 covers the gate 2, and the protection layer 4 is arranged on the organic resin material layer 3. The active layer 5 is arranged on the protection layer 4. That is, the gate 2 of a thin film transistor is arranged on a substrate 1, and the organic resin material layer 3 is formed on the substrate 1 on which the gate 2 is formed. The protection layer 4 is formed on the organic resin material layer 3, and the active layer 5 of the thin film transistor is arranged on the protection layer 4. It can be seen easily that, the thin film transistor on the array substrate is a bottom-gate type thin film transistor. In this case, a source and a drain 8 of the thin film transistor and a pixel electrode 7 of the array substrate are preferably formed by a single patterning process, so that a procedure for manufacturing the array substrate is simple and the productivity thereof can be increased.

As another implementation of the present embodiment, preferably, the protection layer 4 covers the active layer 5, and the organic resin material layer 3 is arranged on the protection layer 4. The gate 2 is arranged on the organic resin material layer 3. That is, the active layer 5 of a thin film transistor is arranged on a substrate 1, and the protection layer 4 is formed on the active layer 5 of the thin film transistor. The organic resin material layer 3 is formed on the protection layer 4, and the gate 2 of the thin film transistor is arranged on the organic resin material layer 3. It can be seen easily that, the thin film transistor on the array substrate is a top-gate type thin film transistor.

Wherein, a material of the protection layer 4 of the array substrate according to the present embodiment may be any one of silicon dioxide, silicon nitride, and aluminum oxide, or another insulating material, and a thickness of the protection layer 4 ranges from 500 Å to 800 Å. A material of the organic resin material layer 3 may be a methacrylic phenolic resin or an epoxy acrylate resin, and a thickness of the organic resin material layer 3 ranges from 1.5 μm to 2.0 μm. A material of the active layer 5 may be any one of indium gallium zinc oxide, indium zinc oxide, indium tin oxide, and indium gallium tin oxide, and another metal oxide semiconductor material may also be used, and a thickness of the active layer 5 ranges from 1500 Å to 2200 Å.

A second embodiment of the present invention will be described below.

The present embodiment provides a display device including the array substrate according to the first embodiment. The display device may be any product or component having a display function, such as an OLED panel, a mobile phone, a tablet computer, a television set, a display, a laptop computer, a digital photo frame, a navigator, and the like.

The display device according to the present embodiment has low power consumption because it includes the array substrate according to the first embodiment.

Of course, the display device according to the present embodiment may further include other conventional structures, such as a power supply unit, a display driving unit, and the like.

A third embodiment of the present invention will be described below.

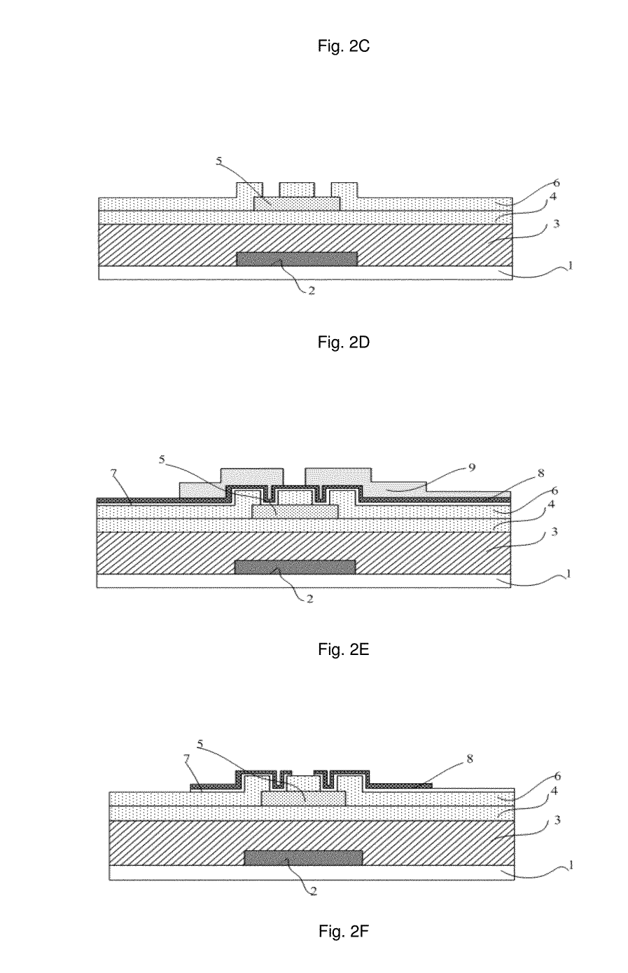

As shown in FIGS. 2A to 2F, the present embodiment provides a method for manufacturing an array substrate, including the following steps:

Step 1: depositing a gate metal layer on a substrate 1 by a magnetron sputtering method, wherein a material of the gate metal layer may be any one of or an alloy of two or more of molybdenum (Mo), aluminum (Al), and copper (Cu), and then a pattern including a gate 2 of a thin film transistor and a gate metal line are formed by a patterning process, as shown in FIG. 2A.

Step 2: forming an organic resin material layer 3 on the substrate 1 on which the Step 1 has been completed. Specifically, the organic resin material layer 3 may be formed by a spin coating method. A thickness of the organic resin material layer 3 ranges from 1.5 μm to 2.0 μm, and a material of the organic resin material layer 3 may be a methacrylic phenolic resin, an epoxy acrylate resin, a non-photosensitive resin, or the like. A curing treatment is performed on the organic resin material layer 3 to form a flat surface (so that a segment difference can be eliminated). Then, a protection layer 4 is deposited on the organic resin material layer 3 having the flat surface, and a thickness of the protection layer 4 ranges from 500 Å to 800 Å. A material of the protection layer 4 may be any one of silicon dioxide, silicon nitride, and aluminum oxide, or may be another insulating material. Thus, a gate insulating layer is formed finally, as shown in FIG. 2B.

Step 3: forming a metal oxide semiconductor material layer on the substrate 1 on which the Step 2 has been completed. Specifically, the metal oxide semiconductor material layer may be formed in an atmosphere of Ar and O₂ at the room temperature by a magnetron sputtering method. Then, a pattern including an active layer 5 of the thin film transistor is formed by a patterning process, as shown in FIG. 2C. Wherein, a material of the metal oxide semiconductor material layer may be any one of indium gallium zinc oxide, indium zinc oxide, indium tin oxide, and indium gallium tin oxide, or may be another oxide semiconductor material, and a thickness of the active layer 5 ranges from 1500 Å to 2200 Å.

Step 4: forming a blocking layer 6 on the substrate 1 on which the Step 3 has been completed, and a material of the blocking layer 6 may be an insulating material such as silicon dioxide, silicon nitride, aluminum oxide, or the like. Then, contact vias, which penetrate through the blocking layer 6 and are used for connecting the active layer 5 of the thin film transistor to the source and the drain 8 thereof, are formed in the blocking layer 6 by a patterning process, as shown in FIG. 2D.

Step 5: depositing a pixel electrode layer, a source-drain metal layer, and a photoresist layer 9 successively on the substrate 1 on which the Step 4 has been completed, and exposing and developing the photoresist layer 9, so that there is no photoresist covering a conductive region of the active layer 5, while the photoresist on the regions corresponding to the source and the drain 8 and the pixel electrode 7 is retained, and a thickness of the photoresist on the regions corresponding to the source and the drain 8 is greater than a thickness of the photoresist on the region corresponding to the pixel electrode 7, as shown in FIG. 2E;

removing the photoresist which has the thickness of the photoresist on the region corresponding to the pixel electrode 7 and an exposed portion of the source-drain metal layer by etching; and

removing the photoresist of the remaining thickness, an exposed portion of the source-drain metal layer, and the exposed pixel electrode layer by etching. In this way, the source and the drain 8 and the pixel electrode 7 are formed finally, as shown in FIG. 2F.

Wherein, a material of the source and the drain 8 may be any one of or an alloy of two or more of molybdenum (Mo), aluminum (Al), and copper (Cu), and a material of the pixel electrode 7 may be indium tin oxide (ITO) or another transparent conductive material. A thickness of each of the source and the drain 8 and the pixel electrode 7 ranges from 400 Å to 700 Å.

Wherein, the photoresist layer 9 may be exposed by using a grayscale mask or a halftone mask. In this way, exposure with different accuracies may be performed on different regions of a single mask by using the single mask according to different requirements.

In the method for manufacturing an array substrate provided by the present embodiment, the gate insulating layer of the thin film transistor has a two-layer structure, wherein, one layer is the organic resin material layer 3, and a material of the organic resin material layer 3 has a low dielectric constant. Thus, the array substrate has low power consumption. Further, the protection layer 4 is formed on the organic resin material layer 3, and thus can effectively prevent the hydroxyls in the organic resin material layer 3 from combining with oxygen ions in a material (e.g., a metal oxide semiconductor material) of the active layer 5; this combination will decrease the performance of the active layer 5. In addition, the pixel electrode 7 and the source and the drain 8 are formed by a single patterning process, causing a procedure for manufacturing the array substrate to be simplified and the cost thereof to be decreased.

A fourth embodiment of the present invention will be described below.

The present embodiment provides another method for manufacturing an array substrate. The method for manufacturing an array substrate in the present embodiment differs from that in the third embodiment in that, the thin film transistor of the array substrate manufactured in the third embodiment is a bottom-gate type thin film transistor, whereas the thin film transistor of the array substrate manufactured in the present embodiment is a top-gate type thin film transistor. The method provided by the present embodiment includes the following steps:

Step 1: forming a metal oxide semiconductor material layer on a substrate 1. Specifically, the metal oxide semiconductor material layer may be formed in an atmosphere of Ar and O₂ at the room temperature by a magnetron sputtering method. Then, a pattern including an active layer 5 of a thin film transistor is formed by a patterning process. Wherein, a material of the metal oxide semiconductor material layer may be any one of indium gallium zinc oxide, indium zinc oxide, indium tin oxide, and indium gallium tin oxide, or may be another oxide semiconductor material, and a thickness of the active layer 5 ranges from 1500 Å to 2200 Å.

Step 2: forming a protection layer 4 on the substrate 1 on which the Step 1 has been completed. Wherein, a thickness of the protection layer 4 ranges from 500 Å to 800 Å, and a material of the protection layer 4 may be any one of silicon dioxide, silicon nitride, and aluminum oxide, or may be another insulating material. Then, an organic resin material layer 3 is formed on the protection layer 4. A thickness of the organic resin material layer 3 ranges from 1.5 μm to 2.0 μm, and a material of the organic resin material layer 3 may be a methacrylic phenolic resin, an epoxy acrylate resin, a non-photosensitive resin, or the like. A curing treatment is performed on the organic resin material layer 3 to form a flat surface (so that a segment difference can be eliminated). Thus, a gate insulating layer is formed finally.

Step 3: depositing a gate metal layer on the substrate 1 on which the Step 2 has been completed by a magnetron sputtering method, wherein a material of the gate metal layer may be any one of or an alloy of two or more of molybdenum (Mo), aluminum (Al), and copper (Cu), and then a pattern including the gate 2 of the thin film transistor and a gate metal line are formed by a patterning process.

Step 4: forming a blocking layer 6 on the substrate 1 on which the Step 3 has been completed, and a material of the blocking layer 6 may be an insulating material such as silicon dioxide, silicon nitride, aluminum oxide, or the like. Then, contact vias, which penetrate through the blocking layer 6 and are used for connecting the active layer 5 of the thin film transistor to the source and the drain 8 thereof, are formed in the blocking layer 6 by a patterning process.

Step 5: forming a pattern including a source and a drain 8 of the thin film transistor on the substrate 1 on which the Step 4 has been completed by a patterning process, the source and the drain 8 being respectively connected to the active layer 5 through the contact vias formed in the Step 4, wherein, a material of the source and the drain 8 may be any one of or an alloy of two or more of molybdenum (Mo), aluminum (Al), and copper (Cu), and a thickness of the source and the drain 8 ranges from 400 Å to 700 Å.

Step 6: forming a passivation layer on the substrate 1 on which the Step 5 has been completed, wherein, a material of the passivation layer is an insulating material, and a contact via penetrating through the passivation layer is formed in the passivation layer in a region corresponding to the drain 8.

Step 7: forming a pattern including a pixel electrode 7 on the substrate 1 on which the Step 6 has been completed by a pattering process, the pixel electrode 7 being connected to the drain of the thin film transistor through the contact via formed in the Step 6, wherein, a material of the pixel electrode 7 may be indium tin oxide (ITO) or another transparent conductive material. A thickness of the pixel electrode 7 ranges from 400 Å to 700 Å.

In the method for manufacturing an array substrate provided by the present embodiment, the gate insulating layer of the thin film transistor has a two-layer structure, wherein, one layer is the organic resin material layer 3, and a material of the organic resin material layer 3 has a low dielectric constant. Thus, the array substrate has low power consumption. Further, the protection layer 4 separates the organic resin material layer 3 and the active layer 5 from each other, and thus can effectively prevent the hydroxyls in the organic resin material layer 3 from combining with oxygen ions in a material (e.g., a metal oxide semiconductor material) of the active layer 5; this combination will decrease the performance of the active layer 5.

It should be understood that, the above embodiments are only exemplary embodiments for the purpose of explaining the principle of the present invention, and the present invention is not limited thereto. For a person having ordinary skill in the art, various improvements and modifications may be applied to the present invention without departing from the spirit and essence of the present invention. These improvements and modifications also fall within the protection scope of the present invention.

1-13. (canceled)

14. An array substrate including a gate, an active layer, and a gate insulating layer separating the gate and the active layer from each other, wherein, the gate insulating layer includes a two-layer structure consisted of an organic resin material layer and a protection layer;
the organic resin material layer is in contact with the gate; and
the protection layer is in contact with the active layer.

15. The array substrate according to claim 14, wherein, the organic resin material layer covers the gate, the protection layer is arranged on the organic resin material layer, and the active layer is arranged on the protection layer.

16. The array substrate according to claim 15, further including a pixel electrode, a source, and a drain; and
the pixel electrode, the source, and the drain are formed by a single patterning process.

17. The array substrate according to claim 14, wherein, the protection layer covers the active layer, the organic resin material layer is arranged on the protection layer, and the gate is arranged on the organic resin material layer.

18. The array substrate according to claim 14, wherein, a material of the protection layer is any one of silicon dioxide, silicon nitride, and aluminum oxide, and a thickness of the protection layer ranges from 500 Å to 800 Å.

19. The array substrate according to claim 14, wherein, a material of the organic resin material layer is a methacrylic phenolic resin or an epoxy acrylate resin, and a thickness of the organic resin material layer ranges from 1.5 μm to 2.0 μm.

20. The array substrate according to claim 14, wherein, a material of the active layer is any one of indium gallium zinc oxide, indium zinc oxide, indium tin oxide, and indium gallium tin oxide, and a thickness of the active layer ranges from 1500 Å to 2200 Å.

21. A display device including an array substrate, wherein
the array substrate includes a gate, an active layer, and a gate insulating layer separating the gate and the active layer from each other, and the gate insulating layer includes a two-layer structure consisted of an organic resin material layer and a protection layer;
the organic resin material layer is in contact with the gate; and
the protection layer is in contact with the active layer.

22. The display device according to claim 21, wherein, the organic resin material layer covers the gate, the protection layer is arranged on the organic resin material layer, and the active layer is arranged on the protection layer.

23. The display device according to claim 22, wherein, the array substrate further includes a pixel electrode, a source, and a drain; and
the pixel electrode, the source, and the drain are formed by a single patterning process.

24. The display device according to claim 21, wherein, the protection layer covers the active layer, the organic resin material layer is arranged on the protection layer, and the gate is arranged on the organic resin material layer.

25. The display device according to claim 21, wherein, a material of the protection layer is any one of silicon dioxide, silicon nitride, and aluminum oxide, and a thickness of the protection layer ranges from 500 Å to 800 Å.

26. The display device according to claim 21, wherein, a material of the organic resin material layer is a methacrylic phenolic resin or an epoxy acrylate resin, and a thickness of the organic resin material layer ranges from 1.5 μm to 2.0 μm.

27. The display device according to claim 21, wherein, a material of the active layer is any one of indium gallium zinc oxide, indium zinc oxide, indium tin oxide, and indium gallium tin oxide, and a thickness of the active layer ranges from 1500 Å to 2200 Å.

28. A method for manufacturing an array substrate, including steps of:
S11: forming a pattern including a gate on a substrate by a patterning process;
S12: forming an organic resin material layer on the substrate on which the step S11 has been completed, and forming a protection layer on the organic resin material layer; and
S13: forming a pattern including an active layer on the substrate on which the step S12 has been completed by a patterning process.

29. The method according to claim 28, wherein, the step S12 of forming the organic resin material layer includes steps of:
coating the organic resin material layer on the substrate on which the gate is formed by a spin coating method; and
performing annealing and curing on the organic resin material layer to form a flat surface.

30. The method according to claim 28, wherein, after the step S13, the method further includes steps of:
S14: forming a blocking layer on the substrate on which the active layer is formed, and forming contact vias which penetrate through the blocking layer on the blocking layer, wherein, the contact vias are used for connecting the active layer to the source and the drain;
S15: depositing a pixel electrode layer, a source-drain metal layer, and a photoresist layer successively on the substrate on which the step S14 has been completed, and exposing and developing the photoresist layer, so that there is no photoresist covering a conductive region of the active layer, while the photoresist on the regions corresponding to the source, the drain, and the pixel electrode is retained, and a thickness of the photoresist on the regions corresponding to the source and the drain is greater than a thickness of the photoresist on the region corresponding to the pixel electrode;
removing the photoresist which has the thickness of the photoresist on the region corresponding to the pixel electrode, and an exposed portion of the source-drain metal layer by etching; and
removing the photoresist of the remaining thickness, an exposed portion of the source-drain metal layer, and the exposed pixel electrode layer by etching.

31. The method according to claim 29, wherein, after the step S13, the method further includes steps of:
S14: forming a blocking layer on the substrate on which the active layer is formed, and forming contact vias which penetrate through the blocking layer on the blocking layer, wherein, the contact vias are used for connecting the active layer to the source and the drain;
S15: depositing a pixel electrode layer, a source-drain metal layer, and a photoresist layer successively on the substrate on which the step S14 has been completed, and exposing and developing the photoresist layer, so that there is no photoresist covering a conductive region of the active layer, while the photoresist on the regions corresponding to the source, the drain, and the pixel electrode is retained, and a thickness of the photoresist on the regions corresponding to the source and the drain is greater than a thickness of the photoresist on the region corresponding to the pixel electrode;
removing the photoresist which has the thickness of the photoresist on the region corresponding to the pixel electrode, and an exposed portion of the source-drain metal layer by etching; and
removing the photoresist of the remaining thickness, an exposed portion of the source-drain metal layer, and the exposed pixel electrode layer by etching.

32. The method according to claim 30, wherein, the step of exposing the photoresist layer is performed by using a grayscale mask.

33. The method according to claim 31, wherein, the step of exposing the photoresist layer is performed by using a grayscale mask.
